(19) United States
(12) Patent Application Publication
(10) Pub. No.: US 2007/0045606 A1
(43) Pub. Date: Mar. 1, 2007

(54) Shaping a phase change layer in a phase change memory cell

(76) Inventors: Michele Magistretti, Gessate (IT); Pietro Petruzza, Pessano Cow Bornago (IT)

Correspondence Address: TROP PRUNER & HU, PC, 1616 S. VOSS ROAD, SUITE 750, HOUSTON, TX, 77057-2631, US

(21) Appl. No.: 11/215,403

(22) Filed: Aug. 30, 2005

(51) Int. Cl. G03F 7/26; H01L 47/00

(52) U.S. Cl. 257/4; 430/311; 430/313; 438/900; 257/E29.17

(57) ABSTRACT

A phase change memory cell includes a phase change layer of a phase change material on a semiconductor body. A hard mask structure is formed on the phase change layer and a resist mask is formed on the hard mask structure. A hard mask is formed by shaping the hard mask structure using the resist mask. The phase change layer is shaped using the hard mask. The resist mask is removed before shaping the phase change layer.

### BACKGROUND

The present invention relates to a method for manufacturing a phase change memory cell.

Phase change memories use a class of materials that switch between two phases having distinct electrical characteristics, associated with two different crystallographic structures of the material, and precisely, an amorphous, disordered phase and a crystalline or polycrystalline, ordered phase. The two phases are hence associated with resistivities of considerably different values.

Currently, the alloys of elements of group VI of the periodic table, such as Te or Se, referred to as chalcogenides or chalcogenic materials, can be used advantageously in phase change memory cells. The currently most promising chalcogenide is formed from an alloy of Ge, Sb and Te (Ge₂Sb₂Te₅), which is now widely used for storing information on overwritable disks and has also been proposed for mass storage.

In the chalcogenides, the resistivity varies by two or more orders of magnitude when the material passes from the amorphous (more resistive) phase to the crystalline (more conductive) phase, and vice versa.

Phase change can be obtained by locally increasing the temperature. Below 150° C., both the phases are stable. Starting from an amorphous state, and rising the temperature above 200° C., there is a rapid nucleation of the crystallites and, if the material is kept at the crystallization temperature for a sufficiently long time, it undergoes a phase change and becomes crystalline. To bring the chalcogenide back to the amorphous state it is necessary to raise the temperature above the melting temperature (approximately 600° C.) and then rapidly cool off the chalcogenide.

One problem in the manufacture of phase change memory devices relates to the step of shaping the chalcogenic layer. More precisely, the above mentioned step involves the use of resist masks and, possibly, hard masks. For example, a resist mask may be formed directly on the chalcogenic layer or, alternatively, is used to form a hard mask from a hard mask layer deposited on the chalcogenic layer. The resist mask and the hard mask need to be removed, once desired chalcogenic structures have been delineated starting from the chalcogenic layer. Chalcogenides, however, may be easily damaged when exposed to etching agents and, in particular, suffer from the chemical substances normally used for removing polymeric structures, such as resist masks. Moreover, significant erosion of the chalcogenic structures is caused by chlorine trapped in polymeric resist mask during the etch of the chalcogenic layer. Chlorine atoms are in fact delivered when the polymer is removed and react with chalcogenides, thereby impairing the chalcogenic structures.

### BRIEF DESCRIPTION OF THE DRAWINGS

For the understanding of the present invention, preferred embodiments thereof are now described, purely as non-limitative examples, with reference to the enclosed drawings, wherein:

FIG. 1 shows a cross-section through a semiconductor device in an initial step of a manufacturing process according to a first embodiment of the present invention;

FIG. 2 is an enlarged top plan view of a detail of FIG. 1, in a subsequent manufacturing step;

FIG. 3 is a cross-section of the detail of FIG. 2 in a subsequent manufacturing step, taken along the line III-III of FIG. 2;

FIG. 4 shows the same view as FIG. 2, in a subsequent manufacturing step;

FIGS. 5 and 6 show the same view as FIG. 3, in subsequent manufacturing steps;

FIG. 7 shows a top plan view of the detail of FIG. 6 in a subsequent manufacturing step;

FIGS. 8 and 9 show a cross-section of the detail of FIG. 7 in a subsequent manufacturing step, taken along the line VII-VII of FIG. 7;

FIG. 10 is a top plan view of the detail of FIG. 9, in a subsequent manufacturing step;

FIG. 11 shows the same view as FIG. 9, in a subsequent manufacturing step;

FIG. 12 shows the same view as FIG. 10, in a subsequent manufacturing step;

FIGS. 13 and 14 are cross-sections of the detail of FIG. 12 in subsequent manufacturing steps, taken along the line XIII-XIII of FIG. 12;

FIG. 15 is a cross-section through the device of FIGS. 1-15, in a final manufacturing step;

FIG. 16 is a simplified circuit diagram of a phase change memory device;

FIGS. 17-27 are cross-sections through a semiconductor device in subsequent manufacturing steps of a process according to a second embodiment of the present invention;

FIG. 28 is a cross-section of the device of FIG. 27, taken along the line XXVIII-XXVIII of FIG. 27;

FIG. 29 is a top plan scanning electron microscope (SEM) view of a semiconductor device made by a process according to the second embodiment of the present invention;

FIG. 30 is a top plan SEM view of a semiconductor device made by a known process; and

FIG. 31 is a system depiction for one embodiment.

### DETAILED DESCRIPTION

In the following description, the term “sublithographic” is used to indicate a linear dimension smaller than the minimum dimension achievable with current ultraviolet (UV) lithographic techniques and, hence, smaller than 100 nm.

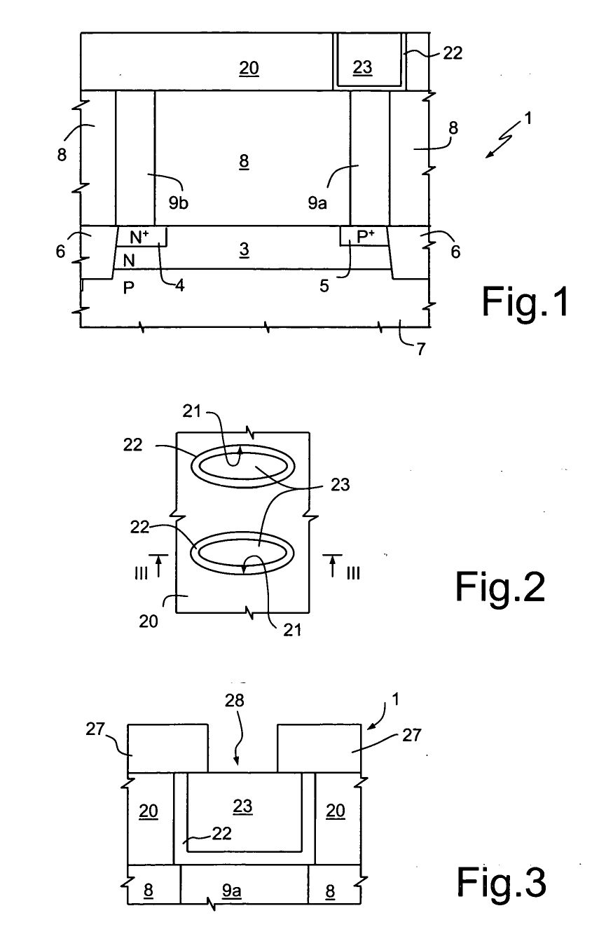

With reference to FIG. 1, a wafer 1 comprising a substrate 7 of semiconductor material, e.g. P-type silicon, may be subjected to standard front end steps to form circuitry components and any element to be integrated into the substrate 7. A plurality of selection transistors, only one of which is shown in FIG. 1, may be made at selected locations in the substrate 7, where storage elements are to be formed in subsequent process steps. In the embodiment of FIG. 1, the selection transistors are PNP bipolar transistors having N-type base regions 3, N⁺-type base contact regions 4 and P⁺-type emitter regions 5. Dielectric regions 6 mutually isolate the selectors 2 from one another.

To build the selectors, a first dielectric layer 8 may be deposited and planarized, after forming the base regions 3. Openings are made in the first dielectric layer 8, above selected areas of the base regions 3. Using two dedicated masks in addition to the self-alignment of the openings, the base contact regions 4 and the emitter regions 5 may be formed by a N⁺ and a P⁺ implant, respectively. Then the openings in the first dielectric layer 8 are covered by a barrier layer, for example of Ti/TiN (not shown), and filled with tungsten to form base contacts 9b and emitter contacts 9a in one embodiment.

Next, a second dielectric layer 20, for example, an undoped silicon glass (USG) layer is deposited, and heaters 22 are made therein, directly on the emitter contacts 9a. In particular, circular or oval openings 21 (FIG. 2) are first formed in the second dielectric layer 20 above the emitter contact 9a. A heating layer, for example of TiN, TiSiN, TiAlN, TiSiC or WCN, is deposited at a sublithographic thickness of 5-50 nm to conformally coat the walls and bottom of the openings. The openings are then completely filled with a dielectric material 23, preferably the same material forming the dielectric layer 20. The heating layer and the dielectric material 23 may be removed outside the openings 21 by chemical mechanical polishing (CMP). Hence, the heaters 22 are in the form of cup-shaped regions filled with the dielectric material 23 and are circular or oval in the top plan view of FIG. 2.

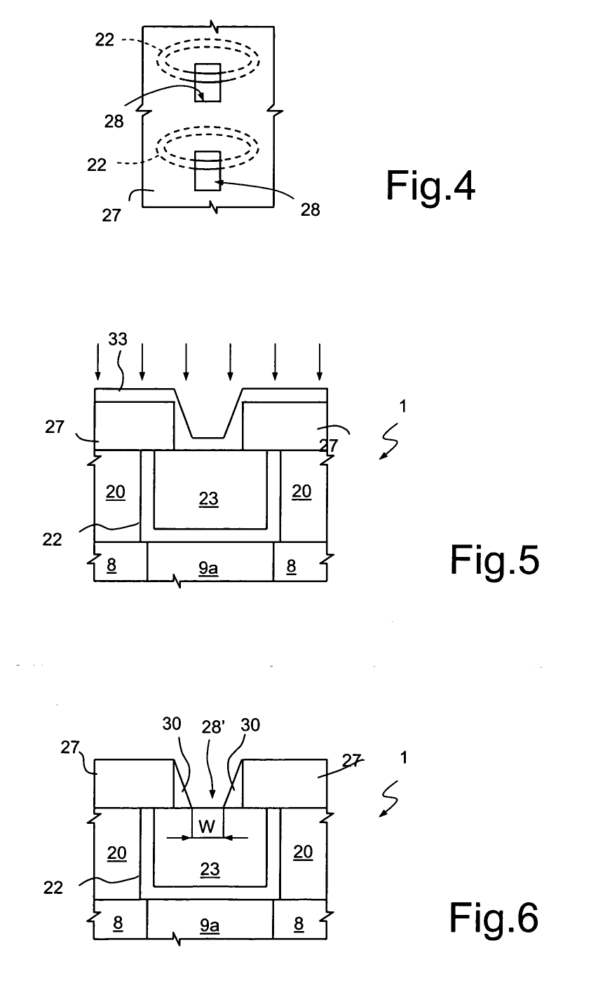

Next, as shown in the enlarged detail of FIG. 3, a mold layer 27, for example of undoped silica glass (USG) or silicon nitride deposited by plasma enhanced chemical vapor deposition (PECVD) or selective area chemical vapor deposition (SACVD), is formed and subsequently etched using a mask, to open slits 28 in one embodiment. The slits 28 cross the respective heaters 22 only once, as shown in FIG. 4.

As shown in FIG. 5, a spacer layer 33, such as silicon dioxide, is conformally deposited on the wafer 1, thereby partly filling the slits 28. Then, referring to FIG. 6, the spacer layer is etched back and spacers 30 are formed along side walls of the slits 28. Microtrenches 28′ are thus formed, which have inclined walls and a sublithographic bottom width W.

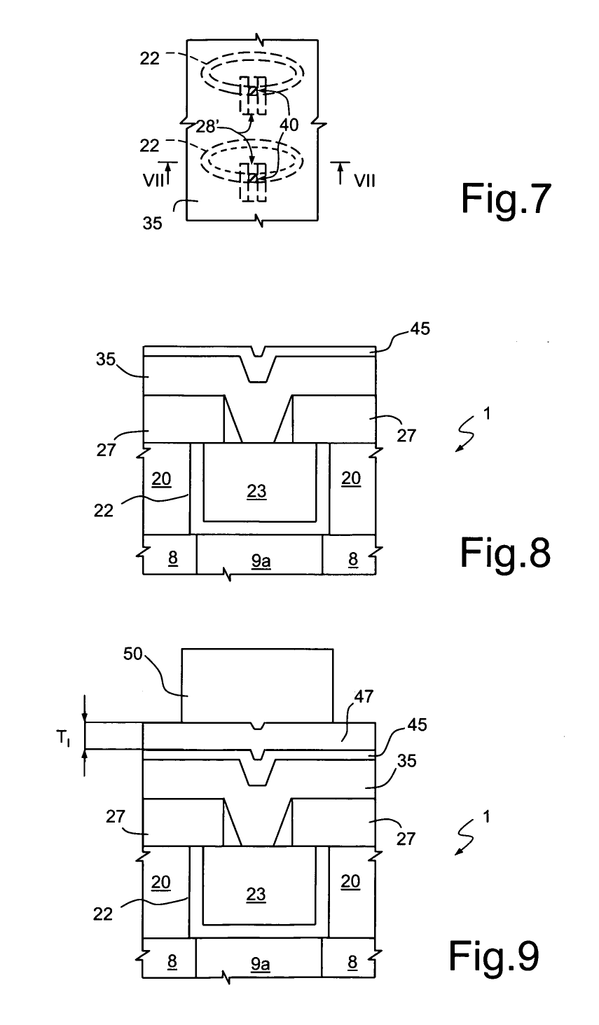

Next, referring to FIGS. 7 and 8, a chalcogenic layer 35 is deposited (also in the present case, for instance, of Ge₂Sb₂Te₅ with a thickness of 60 nm). The chalcogenic layer 35 fills the microtrenches 28′ and contacts the heaters 22 at mutual contact areas. Thus, phase change storage elements 40 (indicated by hatching) are formed at contact areas of the chalcogenic layer 35 with the heaters 22, within the microtrenches 28. Since both the bottom width W of the microtrenches 28′ and the thickness of the heaters 22 are sublithographic, contact areas where storage elements are defined have sublithographic dimensions as well.

As illustrated in FIG. 8, a barrier layer preferably of Ti/TiN, or other suitable material is deposited, to form a cap structure 45, which covers the mold layer 27 and the chalcogenic layer 35. The cap structure 45 has a thickness of around 45 nm in one embodiment.

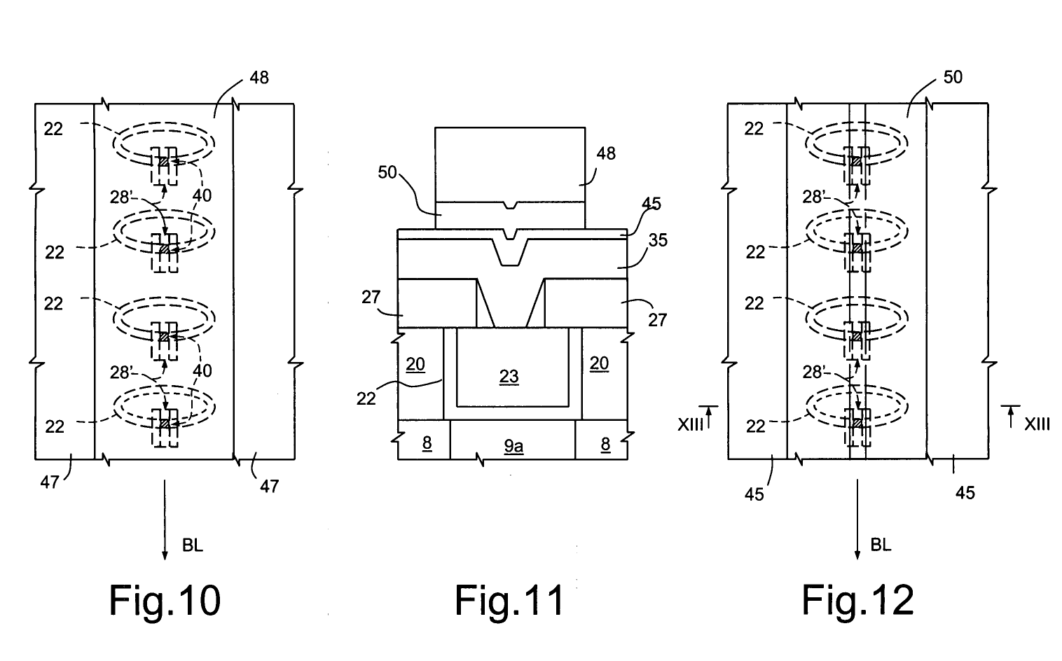

Next, referring to FIGS. 9 and 10, a hard mask structure 47 is deposited on the cap structure 45. The hard mask structure 47 may be made of a dielectric material, such as, for example, SiON, SiN, or alpha carbon. In the embodiment herein described, the hard mask structure 47 is of SiON and has an initial thickness T_{I} of at least around 100 nm, preferably 150 nm.

In another embodiment, the hard mask structure 47 includes a silicon dioxide layer and/or a silicon nitride layer. A resist mask 48 (FIG. 11) may be subsequently created on the hard mask structure 47, substantially above the microtrenches 28′. More precisely, the resist mask 48 includes rectilinear portions that run parallel to a bit line direction BL (perpendicular to the sheet in FIG. 9) and cover microtrenches 28′ accordingly aligned.

As shown in FIG. 11, the hard mask structure 47 is shaped using the resist mask 48 to form a hard mask 50, portions whereof also run parallel to the bit line direction BL above the microtrenches 28′.

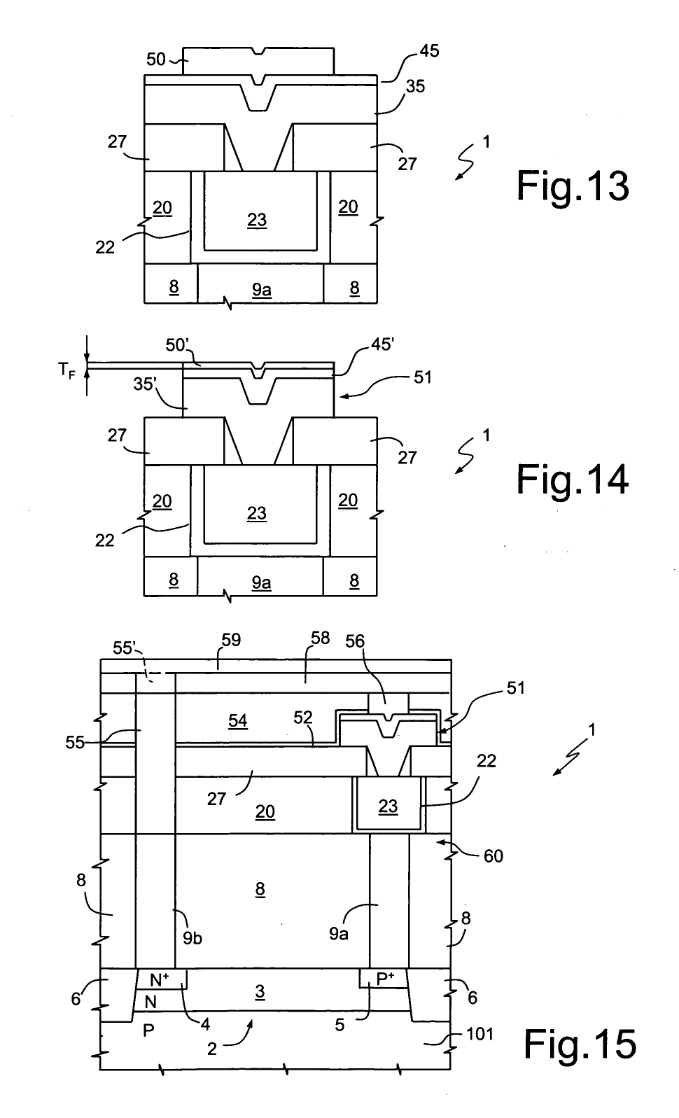

The resist mask 48 is then removed by photoresist stripping (FIGS. 12 and 13) before etching the cap structure 45 and the chalcogenic layer 35. Thus, the adverse effect of Cl or of other reactive substances or compounds trapped in polymeric structures (e.g. the resist mask 48) is substantially eliminated, in some embodiments, and is no longer available for reacting with exposed chalcogenide portions in subsequent process steps. During photoresist stripping, only the cap structure 45 is partially exposed, but portions thereof which may be eventually damaged are in any case to be removed later.

With reference to FIG. 14, the cap structure 45 and the chalcogenic layer 35 are etched using the hard mask 50. Resistive bit lines 51 are thus created, which are in turn parallel to the bit line direction BL and include respective residual portions of the cap structure 45′ and of the chalcogenic layer 35′. Since the resist mask 48 has been previously removed, the hard mask 50 is thinned out during this step as being directly exposed to etching agents. Due to its initial thickness TI, however, the hard mask 50 is only partially etched and a residual portion 50, is left, which has a final thickness TF of around 20-30 nm in some embodiments.

As shown in FIG. 15, a sealing layer 52, of silicon nitride, and a third dielectric layer 54, of silicon dioxide, may be deposited on the wafer 1, planarized and selectively etched to open base plug holes (above the base contacts 9b) and metal bit line trenches. The sealing layer 52 may be made of the same material as the hard mask 52.

Hence, the residual portions 50′ of the hard mask 50 are incorporated in the sealing layer 52 when the latter is deposited. The base plug holes and the metal bit line trenches may be coated by a barrier layer of TaN/Ta (not shown) and filled with Cu, so that, after CMP planarization, base plugs 55 and metal bit lines 56 are made (Cu-damascene technique).

The base plugs 55 may be directly in contact with respective base contacts 9b; and the metal bit lines 56 are formed on and parallel to respective resistive bit lines 51. Finally, a fourth dielectric layer 58 may be deposited and etched to expose the base plugs 55 through holes and to open word line trenches, running perpendicular to the resistive bit lines 51. The holes and the word line trenches may be coated by a further barrier layer of TaN/Ta (not shown), and filled with Cu. The wafer 1 is planarized by CMP to remove Cu and TaN/Ta deposited outside the holes and the word line trenches. Plugs 55′ and metal word lines 59 are thus made (further Cu-damascene technique).

Phase change memory cells 60 and the structure of FIG. 15 are obtained. In particular, the phase change memory cells 60 include one respective storage element 40 and the corresponding heater 22 and selection transistor 2. The process flow combines with the formation of metal levels (not shown).

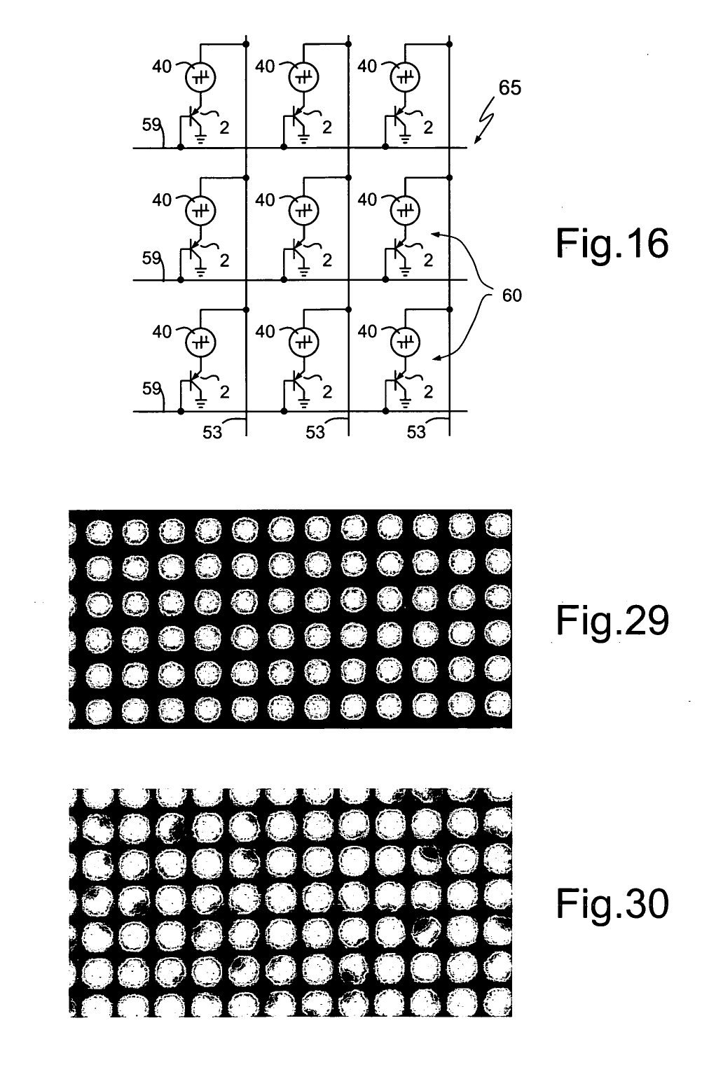

As illustrated in FIG. 16, phase change memory cells 60 are arranged in rows and columns to form a phase change memory device 65, which further includes known control, reading and programming circuits (here not shown). In particular, FIG. 16 shows portions of three columns, with the respective metal bit lines 53, and of two rows, with the respective word lines 59.

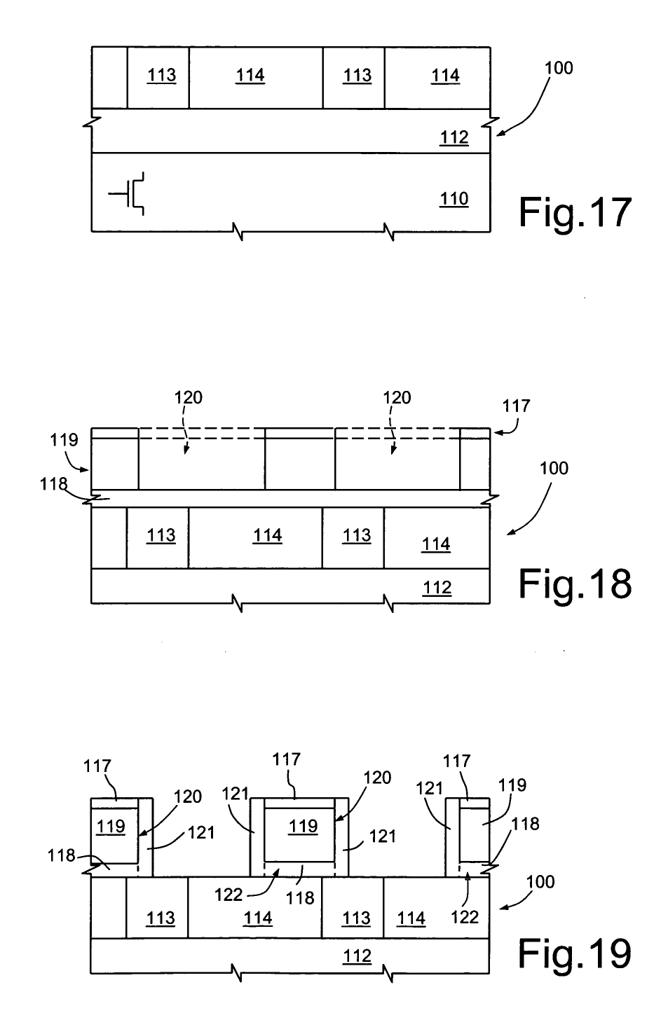

A second embodiment is shown in FIGS. 17-27.

With reference to FIG. 17, a wafer 100 including a substrate 110 of semiconductor material, e.g. silicon, is initially processed to form circuitry components and any element to be integrated into the substrate 110.

Then, the wafer 100 is coated by an insulating layer 112. Word lines 113 (e.g. of copper) are formed of the insulating layer 112, insulated from each other by a first dielectric layer 114. The word lines 113 may be formed by depositing the first dielectric layer 114, then removing the dielectric material where the word lines 113 are to be formed, and filling the trenches so obtained with copper (Cu). Any excess copper is then removed from the surface of the wafer 100 by CMP (“Cu-damascene” process).

Thereafter, (FIG. 18) an encapsulating structure is created. The encapsulating structure may be formed by depositing, in sequence, a first nitride layer 118, a first oxide layer 119 and a glue layer 117 and then selectively removing the first nitride layer 118, the first oxide layer 119 and the glue layer 117 down to the surface of the first dielectric layer 114. Thus, for each word line 113, openings 120 are formed, which extend at least in part above the word line 113. Each opening 120 may extend along the whole respective word line 113 or along only a part thereof, in which case a plurality of openings 120 extend aligned to each other along each word line 113. Glue regions 117 are defined around the openings 120 in one embodiment.

Then, referring to FIG. 19, a spacer layer, e.g. of silicon nitride, is deposited and etched back. Thus, the horizontal portions of the spacer layer are removed, and only vertical portions thereof, indicated at 121 and extending along the vertical walls of the opening 120, are left. These vertical portions 121 join the first nitride layer 118, laterally of the openings 120, and form, with the first nitride layer 118, a protective region indicated by 122. The protective region 122 together with the first oxide layer 119 form an encapsulating structure.

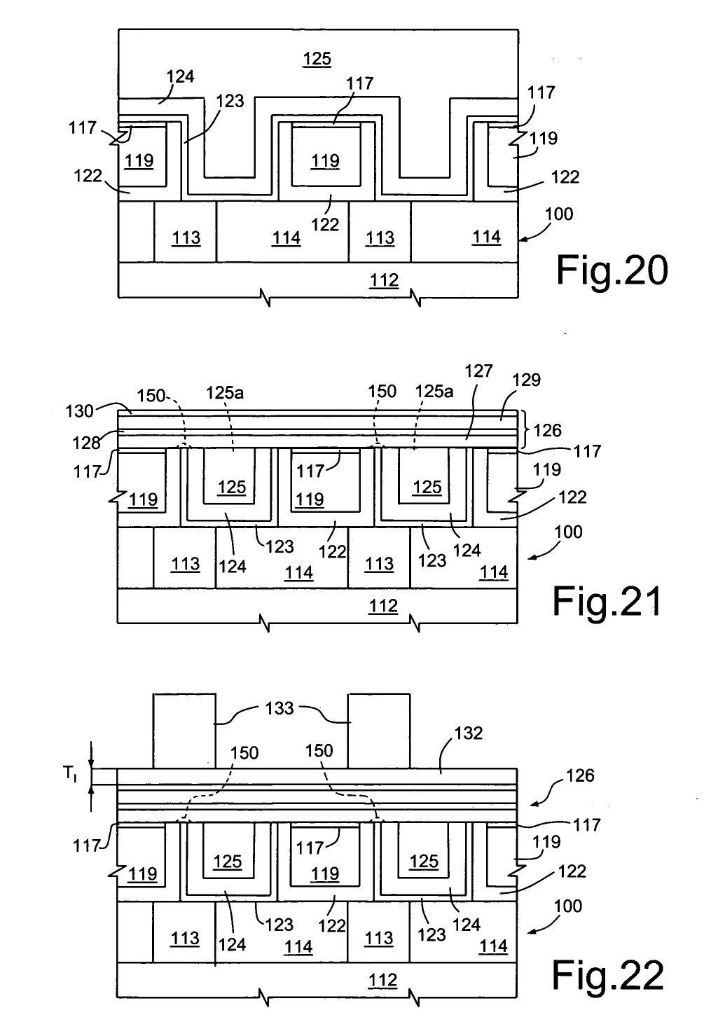

Thereafter, a heater layer 123, e.g. of TiSiN, is deposited and conformally covers the underlying structure as shown in FIG. 20. One vertical wall of the heater layer 123 extends on and in contact with a respective word line 113. Subsequently, a sheath layer 124, e.g. of silicon nitride, and a second dielectric layer 125 are deposited in some cases. The second dielectric layer 125 may completely fill the openings 120 to complete the encapsulating structure.

The structure is then planarized by CMP (Chemical Mechanical Polishing), thus removing all portions of the second dielectric layer 125, of the sheath layer 124 and of the heater layer 123 extending outside the openings 120 and exposing the glue regions 117.

Next, referring to FIG. 21, an Ovonic Memory Switch/Ovonic Threshold Switch (OMS/OTS) stack 126 is deposited. In detail, a first chalcogenic layer 127 (e.g., Ge₂Sb₂Te₅), a first barrier layer 128 (e.g., TiAlN), a second chalcogenic layer 129 (e.g., As₂Se₃) and a second barrier layer 130 (e.g., TiAlN) are deposited in one embodiment. The above materials are only indicative, and any chalcogenic material suitable to store information depending on its physical state (for first chalcogenic layer 127) and to operate as a selector for second chalcogenic layer 129) may be used. Storage elements 150 are formed at a mutual contact areas of the heating layer 123 and the first chalcogenic layer 127.

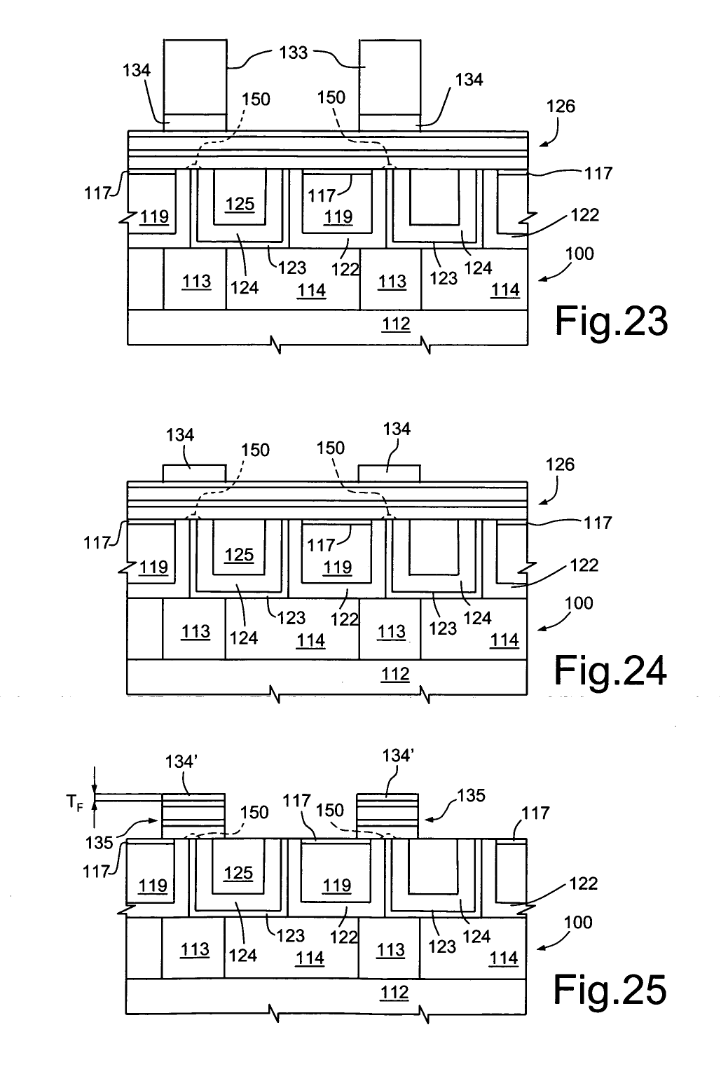

Then, using FIG. 22, a hard mask structure 132 of SiON (150 nm thick) is deposited on the second barrier layer 130 and is shaped using a resist mask 133, which includes approximately circular, oval or square mask portions arranged above respective storage elements 150 (FIG. 23). In another embodiment, the hard mask structure 132 is made of a different dielectric material, such as SiN or alpha carbon. Thus, a hard mask 134 is formed from the hard mask structure 132 and circular, oval or square mask portions includes circular, oval or square mask portions as well.

The resist mask 133 may be removed by photoresist stripping before etching the OMS/OTS stack 126, as shown in FIG. 24.

Then, in FIG. 25, the OMS/OTS stack 126 is shaped using only the hard mask 134, thereby, so called “dots” 135 are formed, each including a respective storage elements 150. Since the resist mask 133 has been previously removed, the hard mask 134 is thinned out during this step as being directly exposed to etching agents. Due to its initial thickness T_{I}, however, the hard mask 134 is only partially etched and a residual portion 134′ is left, which has a final thickness T_{F} of around 20-30 nm.

After completely removing the residual portion 134′ of the hard mask 134, a sealing layer 136, e.g. of silicon nitride, and an intermetal layer 137 of insulating material (e.g. of silicon dioxide) are deposited. Thus, the structure of FIG. 26 is obtained.

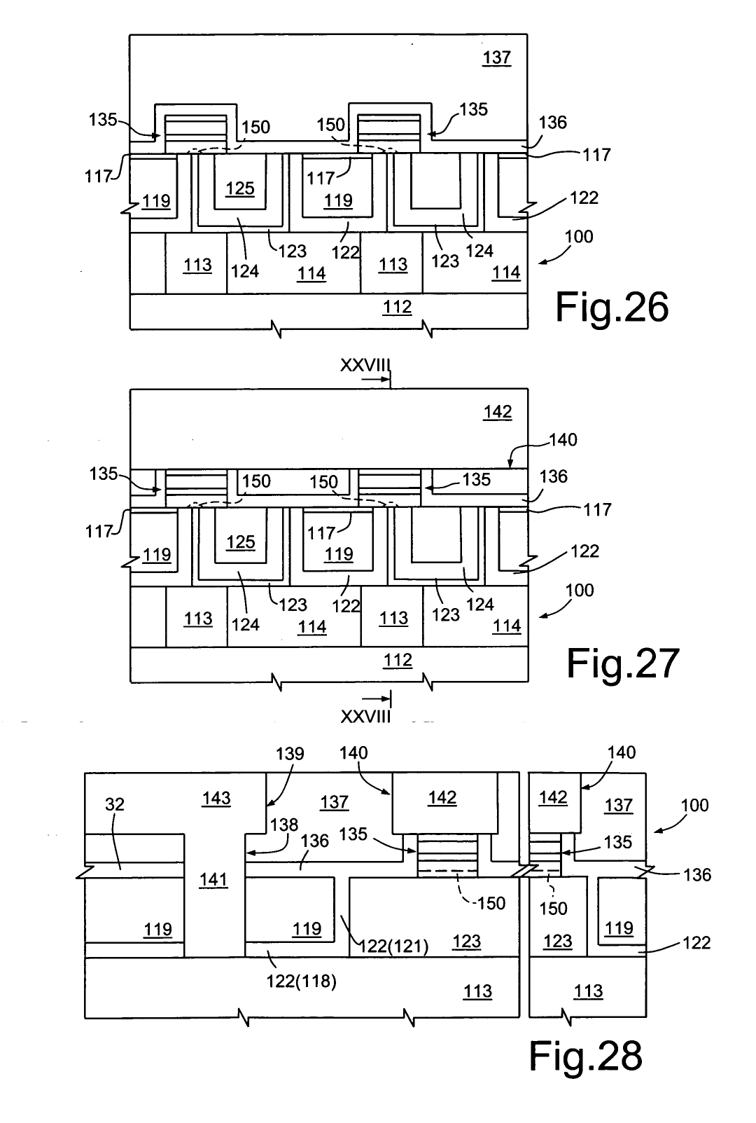

Finally, the wafer 100 is subjected to CMP to planarize the structure and bit lines and vias are formed, preferably using a standard dual Cu-damascene process. To this end, FIG. 27, preferably the intermetal layer 137 and the first dielectric layer 114 (as well as the sealing layer 136 and the bottom of the protective region 122, where present) are etched in a two-step process to form vias openings 138 (extending down to the word lines 113), row connection trenches 139 and column trenches 140 (extending down to the dots 131). The two etching step may be carried out in any sequence. Then, a metal material (e.g. Cu) is deposited that fills the vias openings 138 and the column trenches 140, forming vias 141 and bit lines 142. Furthermore, word line connections 143 are also formed. Thus the structure of FIGS. 27 and 28 is obtained.

As shown in FIGS. 27 and 28, the heater layer 123 form heaters or resistive elements having substantially box-like shapes with a first vertical elongated wall 123a (on the left, in the drawings) extending approximately above the midline of the respective word line 113 and a second vertical elongated wall 123b (on the right) extending on top of the first oxide layer 119. Each first vertical elongated wall 123a forms a wall-shaped heater that contacts the respective dots 131 along a line and is shared by all the dots 131 aligned on a single word line 113, while the second vertical elongated wall 123b has no function. The electrical connection of all the dots 131 along a same word line through the wall-shaped heater 123 may not impair the operation of the memory device in some embodiments, since the second chalcogenic material 129 of the dots 131 form an OTS or selection element allowing addressing only the dots 131 connected to both the word line 113 and the bit line 142 that are addressed.

The chalcogenic structures included either in the resistive bit lines 51 (FIGS. 14 and 15) or in the dots 135 (FIGS. 25-28) may be prevented from reacting with chemical agents which would cause erosion and damage in some embodiments. In fact, polymers (resist mask) may be removed before shaping the deposited chalcogenic material. Accordingly, only a superficial portion of the chalcogenic material is exposed and may be damaged in some cases. However, such superficial portion is ultimately removed to form the chalcogenic structures and is not to be included in the final cell. The hard mask may have a final thickness of few nanometers only after shaping the chalcogenic layer, and may be easily removed if required, without causing any damage to the chalcogenic structures in some cases. Otherwise, residual portions of the hard mask structure may be left and incorporated in the sealing layer. Therefore, the final cells may include chalcogenic structures which are precisely shaped and have high quality.

By way of example, FIGS. 29 and 30 show top plan views of phase change memory devices having dot type memory cells. The device of FIG. 29 is made by the above described process and has dots of clearly higher quality compared to the dots of the device of FIG. 30, which is made by a conventional process. The dots of the device of FIG. 29, in fact, do not show erosion.

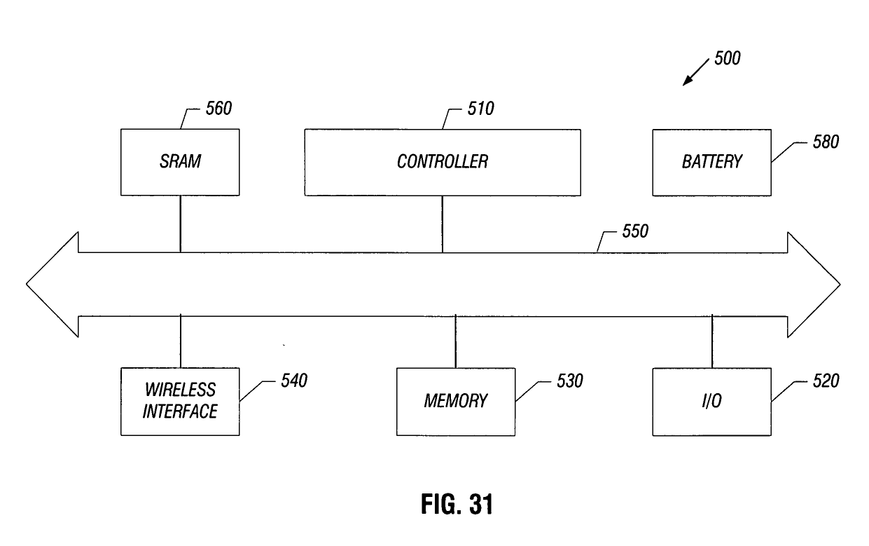

Turning to FIG. 31, a portion of a system 500 in accordance with an embodiment of the present invention is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, a cellular network, although the scope of the present invention is not limited in this respect.

System 500 may include a controller 510, an input/output (I/O) device 520 (e.g. a keypad, display), static random access memory (SRAM) 560, a memory 530, and a wireless interface 540 coupled to each other via a bus 550. A battery 580 may be used in some embodiments. It should be noted that the scope of the present invention is not limited to embodiments having any or all of these components.

Controller 510 may comprise, for example, one or more microprocessors, digital signal processors, microcontrollers, or the like. Memory 530 may be used to store messages transmitted to or by system 500. Memory 530 may also optionally be used to store instructions that are executed by controller 510 during the operation of system 500, and may be used to store user data. Memory 530 may be provided by one or more different types of memory. For example, memory 530 may comprise any type of random access memory, a volatile memory, a non-volatile memory such as a flash memory and/or a memory such as memory discussed herein.

I/O device 520 may be used by a user to generate a message. System 500 may use wireless interface 540 to transmit and receive messages to and from a wireless communication network with a radio frequency (RF) signal. Examples of wireless interface 540 may include an antenna or a wireless transceiver, although the scope of the present invention is not limited in this respect.

Finally, numerous modifications and variations may be made to the process described and illustrated herein, all falling within the scope of the invention, as defined in the attached claims. In particular, the process may be exploited for manufacturing any type of phase change memory cells. For example, phase change memory cells having lance type heaters may be made. Lance heaters are conventionally made by opening holes in a dielectric layer, possibly reducing a cross dimension of the holes to a sublithographic extension by depositing and etching back a spacer layer, and filling the holes with a heater material, before CMP planarization. A chalcogenic layer is then deposited and shaped as above described, to form dots on the heaters. Phase change storage elements are defined at contact areas of dots with the respective heaters.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a phase change layer of a phase change material on a semiconductor body;
creating a hard mask structure on said phase change layer;
creating a resist mask on said hard mask structure;
forming a hard mask by shaping said hard mask structure using said resist mask;
removing said resist mask; and
shaping said phase change layer using said hard mask after removing said resist mask.

2. The method according to claim 1 wherein creating a hard mask structure includes forming a hard mask structure that includes a dielectric material.

3. The method according claim 1 wherein shaping said phase change layer comprises at least partially removing said hard mask.

4. The method according to claim 1 comprising forming a cap structure on said phase change layer, said hard mask structure being formed in contact with said cap structure.

5. The method according to claim 1 wherein removing said resist mask comprises photoresist stripping.

6. The method according to claim 1 further comprising forming a dielectric structural layer on said semiconductor body and a heater element in said dielectric structural layer.

7. The method according to claim 6 wherein forming said phase change layer comprises depositing said phase change layer directly in contact with said heater element, thereby defining a storage element at a contact area of said heater element and said phase change layer.

8. The method according to claim 7 wherein defining a storage element includes defining the element at said contact area that has at least one sublithographic dimension.

9. A semiconductor structure comprising:
a chalcogenide layer;
a barrier layer covering said chalcogenide; and
a mask layer over said barrier layer.

10. The structure of claim 9 wherein said barrier layer includes metal.

11. The structure of claim 10 wherein said metal includes titanium.

12. The structure of claim 11 wherein said metal includes Ti/TiN.

13. The structure of claim 12 wherein said barrier layer is around 45 nm.

14. The structure of claim 9 wherein said barrier layer completely covers said chalcogenide layer.

15. The structure of claim 9 including a resist mask over said barrier layer.

16. The structure of claim 9 including a hard mask over said barrier layer.

17. The structure of claim 16 including a resist mask over said hard mask.

18. The structure of claim 9 including two separate chalcogenide layers.

19. A product formed by a process comprising:
forming a phase change layer of a phase change material on a semiconductor body;
creating a hard mask structure on said phase change layer;
creating a resist mask on said hard mask structure;
forming a hard mask by shaping said hard mask structure using said resist mask;
removing said resist mask; and
shaping said phase change layer using said hard mask after removing said resist mask.

20. The product of claim 19 formed by a process wherein shaping said phase change layer comprises at least partially removing said hard mask.

21. The product of claim 19 formed by a process comprising forming a cap structure on said phase change layer, said hard mask structure being formed in contact with said cap structure.

22. The product of claim 19 formed by a process wherein removing said resist mask comprises photoresist stripping.

23. The product of claim 19 formed by a process further comprising forming a dielectric structural layer on said semiconductor body and a heater element in said dielectric structural layer.

24. The product of claim 23 formed by a process wherein forming said phase change layer comprises depositing said phase change layer directly in contact with said heater element, thereby defining a storage element at a contact area of said heater element and said phase change layer.

25. The product of claim 24 formed by a process wherein defining a storage element includes defining the element at said contact area that has at least one sublithographic dimension.

26. The product of claim 19 wherein said product includes a processor and a phase change memory including said phase change layer.
